(19) United States
(12) Patent Application Publication
(10) Pub. No.: US 2024/0258410 A1
(43) Pub. Date: Aug. 1, 2024

(54) SEMICONDUCTOR DEVICES

(71) Applicant: Samsung Electronics Co., Ltd., Suwon-si (KR)

(72) Inventors: Dongwoo Kim, Suwon-si (KR); Jinbum Kim, Suwon-si (KR)

(21) Appl. No.: 18/531,836

(22) Filed: Dec. 7, 2023

(30) Foreign Application Priority Data
Jan. 27, 2023 (KR) 10-2023-0010492

(51) Int. Cl. H01L 29/732; H01L 23/528; H01L 29/66

(52) U.S. Cl. CPC H01L 29/7325; H01L 23/5286; H01L 29/66287

(57) ABSTRACT

A semiconductor device includes a substrate having a recessed region, a first semiconductor region including a first semiconductor layer on a bottom surface and an inner side surface of the recessed region and a first protrusion on the first semiconductor layer, and having a first conductivity type, a second semiconductor region including a second semiconductor layer on the first semiconductor layer and a second protrusion on the second semiconductor layer, and having a second conductivity type, a third semiconductor region including a third semiconductor layer on the second semiconductor layer and a third protrusion on the third semiconductor layer, and having the first conductivity type, a epitaxial stopper layer covering the bottom surface of the recessed region between the first semiconductor region and the substrate and including a material different from materials of the first semiconductor region, and a dummy gate structure intersecting the first to third protrusions on the substrate.

### CROSS-REFERENCE TO RELATED APPLICATION(S)

This application claims the benefit under 35 USC 119(a) of Korean Patent Application No. 10-2023-0010492 filed on Jan. 27, 2023 in the Korean Intellectual Property Office, the entire disclosure of which is incorporated herein by reference for all purposes.

### BACKGROUND

The present inventive concept relates to semiconductor devices.

As demands for high performance, high speed, and/or multifunctionality of semiconductor devices increase, the degree of integration of semiconductor devices is increasing. In manufacturing a semiconductor device with a fine pattern corresponding to the trend for high integration of semiconductor devices, it is necessary to implement patterns having a fine width or a fine separation distance. In addition, to improve the degree of integration, efforts are being made to develop a semiconductor device having a BackSide Power Delivery Network (BSPDN) structure in which a power rail is disposed on the backside surface of a wafer.

### SUMMARY

Example embodiments provide a semiconductor device having improved integration and electrical characteristics.

According to example embodiments, a semiconductor device includes a substrate having a recessed region; a first semiconductor region including a first semiconductor layer on a bottom surface and an inner side surface of the recessed region and a first protrusion on an upper surface of the first semiconductor layer, and having a first conductivity type; a second semiconductor region including a second semiconductor layer on the first semiconductor layer in the recessed region and a second protrusion on an upper surface of the second semiconductor layer, and having a second conductivity type; a third semiconductor region including a third semiconductor layer on the second semiconductor layer in the recessed region and a third protrusion on an upper surface of the third semiconductor layer, and having the first conductivity type; an epitaxial stopper layer covering the bottom surface of the recessed region, between the first semiconductor region and the substrate, and including a material different from materials of the first to third semiconductor regions; and a dummy gate structure extending and intersecting the first to third protrusions on the substrate.

According to example embodiments, a semiconductor device includes a substrate having a first region on which a recessed region is disposed and a second region; a first semiconductor region on a bottom surface and an inner side surface of the recessed region and including first conductivity type impurities; a second semiconductor region on the first semiconductor region in the recessed region and including second conductivity type impurities; a third semiconductor region on the second semiconductor region in the recessed region and including the first conductivity type impurities; and an epitaxial stopper layer covering at least a portion of outer surfaces of the first semiconductor region including a bottom surface. Each of the first to third semiconductor regions is formed of an epitaxial layer.

According to example embodiments, a semiconductor device includes a substrate having a recessed region; a first semiconductor region on a bottom surface and an inner side surface of the recessed region and including first conductivity type impurities; a second semiconductor region on the first semiconductor region in the recessed region and including second conductivity type impurities; a third semiconductor region on the second semiconductor region in the recessed region and including the first conductivity type impurities; and an epitaxial stopper layer covering at least a portion of outer surfaces of the first semiconductor region including a bottom surface. The first to third semiconductor regions and the epitaxial stopper layer have a region entirely overlapping in a direction, perpendicular to an upper surface of the substrate.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a semiconductor device according to example embodiments;

FIGS. 2A and 2B are cross-sectional views illustrating a semiconductor device according to example embodiments;

FIGS. 3A to 3C are schematic cross-sectional views illustrating a semiconductor device according to example embodiments;

FIGS. 4A and 4B are schematic cross-sectional views illustrating a semiconductor device according to example embodiments;

FIG. 5 is a plan view illustrating a semiconductor device according to example embodiments;

FIG. 6 illustrates cross-sectional views illustrating a semiconductor device according to example embodiments; and

FIGS. 7A to 7H are views illustrating a process sequence to describe a method of manufacturing a semiconductor device according to example embodiments.

### DETAILED DESCRIPTION

Hereinafter, with reference to the accompanying drawings, example embodiments will be described as follows. It can be understood the terms such as ‘on’, ‘upper portion’, ‘upper surface’, ‘below’, ‘lower portion’, ‘lower surface’, ‘side’, ‘side surfaces’ and the like are referred to the drawings as references, except where indicated by reference numerals and referred to separately.

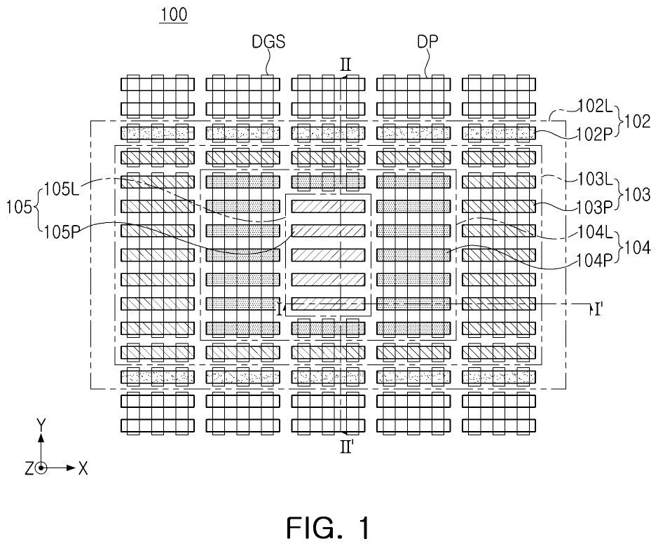

FIG. 1 is a plan view illustrating a semiconductor device according to example embodiments.

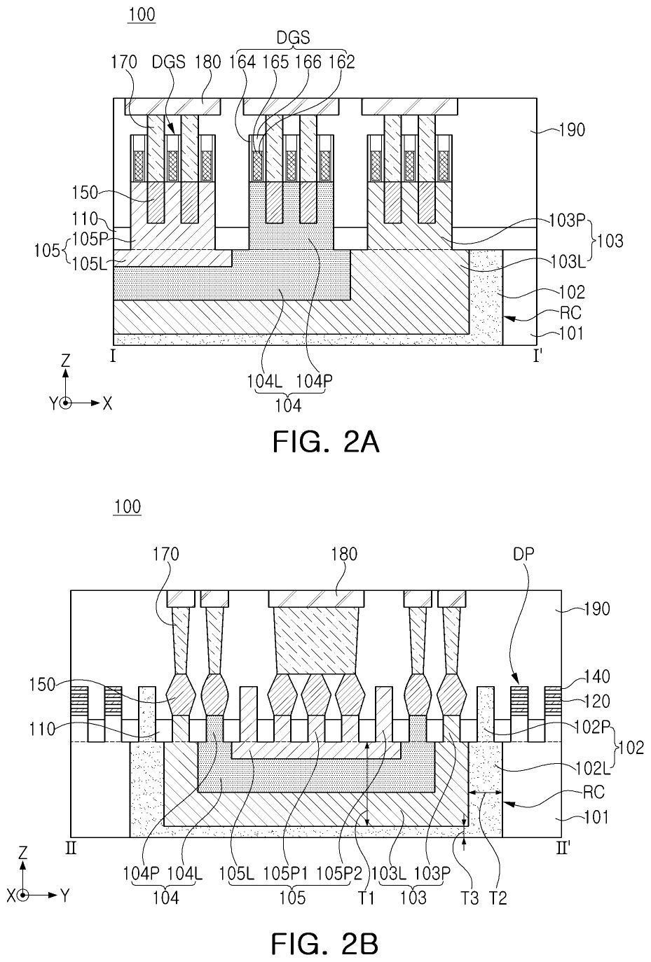

FIGS. 2A and 2B are cross-sectional views illustrating a semiconductor device according to example embodiments. FIGS. 2A and 2B illustrate cross-sections of the semiconductor device of FIG. 1 taken along cutting lines I-I′ and II-II′, respectively. For convenience of descriptions, only some components of the semiconductor device are illustrated in FIG. 1.

Referring to FIGS. 1 to 2B, a semiconductor device 100 may include a substrate 101 having a recessed region RC, first to third semiconductor regions 103, 104, and 105 sequentially disposed in the recessed region RC, an epitaxial stopper layer 102 disposed between the first semiconductor region 103 and the substrate 101, and dummy gate structures (DGS) disposed on the substrate 101. The semiconductor device 100 may further include dummy protrusions DP outside of the first to third semiconductor regions 103, 104, and 105, a device isolation layer 110 between upper regions of the first to third semiconductor regions 103, 104, and 105, source layers 150 disposed on both sides of the dummy gate structures DGS, contact plugs 170 connected to the source layers 150, interconnection lines 180 connected to the contact plugs 170, and an interlayer insulating layer 190.

The semiconductor device 100 may be a bipolar junction transistor (BJT) including a first semiconductor region 103 functioning as a collector, a second semiconductor region 104 serving as a base, and a third semiconductor region 105 functioning as an emitter. The semiconductor device 100 may be a PNP device or an NPN device, and an example of a PNP device will be mainly described below. For example, the semiconductor device 100 may be a vertical PNP device in which the first to third semiconductor regions 103, 104, and 105 are vertically disposed. The substrate 101 may be a base on which the semiconductor device 100 is manufactured and may include a well region. The substrate 101 may have a recessed region RC formed by removal of part of an upper surface of substrate 101. The recessed region may be an area (channel, cavity etc.) that is removed from the original substrate (e.g., removed from a crystalline semiconductor wafer) to form an area recessed below the original upper surface of the substrate. The substrate 101 may be provided as a bulk wafer, an epitaxial layer, a Silicon On Insulator (SOI) layer, or a Semiconductor On Insulator (SeOI) layer. The substrate 101 may include a semiconductor material, such as a Group IV semiconductor, a Group III-V compound semiconductor, or a Group II-VI compound semiconductor. For example, the group IV semiconductor may include silicon, germanium or silicon-germanium. The substrate 101 may include first conductivity-type impurities, for example, P-type impurities, but is not limited thereto.

The first semiconductor region 103 may include a first semiconductor layer 103L disposed on the bottom and inner side surfaces of the recessed region RC, and first protrusions 103P disposed on the upper surface of the first semiconductor layer 103L, and have a first conductivity type. The first semiconductor layer 103L may be a region disposed in the recessed region RC, and the first protrusions 103P may be regions protruding from the upper surface of the first semiconductor layer 103L. First protrusions 103P may extend beyond an upper surface of substrate 101 in the Z direction, and may be regions protruding in a columnar shape in the form of a line extending in the X-direction. In example embodiments, the number and height of the first protrusions 103P may be changed.

The first semiconductor region 103 may be an epitaxial layer including a semiconductor material. The first semiconductor region 103 may include the first conductivity-type impurities, for example, P-type impurities. In an example embodiment, when the substrate 101 includes the first conductivity type impurities, the concentration of the first conductivity type impurities may be higher in the first semiconductor region 103 than in the substrate 101. The thickness of the first semiconductor region 103, for example the thickness of first semiconductor layer 103L in the Z-direction, may range, for example, from about 30 nm to about 200 nm. The first semiconductor region 103 may be a crystalline silicon region, for example having a single domain epitaxy, which is the growth of a crystal layer with one well-defined orientation with respect to the crystal of the substrate 101.

The second semiconductor region 104 may include a second semiconductor layer 104L disposed on the first semiconductor layer 103L in the recessed region RC, and second protrusions 104P disposed on the upper surface of the second semiconductor layer 104L, and may have a second conductivity type different from the first conductivity type. The second semiconductor layer 104L may be a region disposed in the recessed region RC, and the second protrusions 104P may be regions protruding from the upper surface of the second semiconductor layer 104L. Second protrusions 104P may extend beyond an upper surface of substrate 101 in the Z-direction, and may be regions protruding in a columnar shape in the form of a line extending in the X-direction.

The second semiconductor region 104 may be an epitaxial layer including a semiconductor material. The second semiconductor region 104 may include second conductivity-type impurities, for example, N-type impurities. The thickness of the second semiconductor region 104, for example the thickness of second semiconductor layer 104L in the Z-direction, may range, for example, from about 60 nm to about 400 nm.

The third semiconductor region 105 may include a third semiconductor layer 105L disposed on the second semiconductor layer 104L in the recessed region RC, and third protrusions 105P disposed on the upper surface of the third semiconductor layer 105L, and may have the first conductivity type. The third semiconductor layer 105L may be a region disposed in the recessed region RC, and the third protrusions 105P may be regions protruding from the upper surface of the third semiconductor layer 105L. Third protrusions 105P may extend beyond an upper surface of substrate 101 in the Z-direction, and may be regions protruding in a line-shaped column shape extending in the X-direction. As illustrated in FIG. 2B, the third protrusions 105P may include third inner protrusions 105P1 and third outer protrusions 105P2 having different heights. However, in some embodiments, the number of third outer protrusions 105P2 may be changed or may be omitted.

The third semiconductor region 105 may be an epitaxial layer including a semiconductor material. The third semiconductor region 105 may include the first conductivity-type impurities, for example, P-type impurities. The thickness of the third semiconductor region 105, for example the thickness of third semiconductor layer 105L in the Z-direction, may range, for example, from about 30 nm to about 200 nm. The first semiconductor layer 103L, the second semiconductor layer 104L, and the third semiconductor layer 105L may each be an epitaxially grown crystalline silicon region deposited within the recessed region RC, for example having a single domain epitaxy, which is the growth of a crystal layer with one well-defined orientation with respect to the crystal of the substrate 101. The first, second and third protrusions (103P, 104P and 105P respectively) may also be epitaxially grown crystalline silicon regions, for example having a single domain epitaxy, and formed on the first, second and third semiconductor layers (103L, 104L and 105L) respectively.

In a plan view, the first semiconductor region 103 may surround the second semiconductor region 104, and the second semiconductor region 104 may surround the third semiconductor region 105. For example, in a plan view, the first semiconductor region 103 covers a greater surface area than the second semiconductor region 104, which in turn covers a greater surface area than third semiconductor region 105. First semiconductor layer 103L can be disposed to fully separate the second semiconductor layer 104L from substrate 101 (and/or epitaxial stopper layer 102). Also, second semiconductor layer 104L can be disposed to fully separate the third semiconductor layer 105L from first semiconductor layer 103L Accordingly, in at least one direction, for example, the X-direction and/or the Y-direction, the second protrusions 104P may be disposed between the first protrusions 103P, and the third protrusions 105P may be disposed between the second protrusions 104P. In the semiconductor device 100, the first to third semiconductor layers 103L, 104L, and 105L may vertically overlap each other to form a vertical PNP device. In the vertical direction, for example, the Z-direction, the first to third semiconductor layers 103L, 104L, and 105L may have a vertically overlapping region. The third semiconductor layer 105L may vertically overlap the first and second semiconductor layers 103L and 104L, and the second semiconductor layer 104L may vertically overlap the first semiconductor layer 103L. In the example of FIGS. 2A and 2B, the entire region of third semiconductor region 105 is disposed above at least part of second semiconductor region 104, and the entire second semiconductor region 104 is disposed above at least part of first semiconductor region 103.

The first to third protrusions 103P, 104P, and 105P extend in the X-direction as illustrated in FIG. 1, and may be spaced apart from each other in the Y-direction. The first to third protrusions 103P, 104P, and 105P may also be referred to as fin regions or active regions. In example embodiments, the number and height of each of the first to third protrusions 103P, 104P, and 105P may be changed. As illustrated in FIG. 2B, at least a portion of the first to third protrusions 103P, 104P, and 105P may have a recessed region outside of the dummy gate structures DGS. Source layers 150 may be disposed in the recessed regions.

Each of the first to third semiconductor regions 103, 104, and 105 may be an epitaxially grown layer, and may be an in-situ doped layer during the growth process. Accordingly, a change in the doping profile at the boundary of each of the first to third semiconductor regions 103, 104, and 105 may be distinct compared to an example formed by an ion implantation process. As illustrated in FIG. 2B, the first thickness T1 from the lower surface of the first semiconductor layer 103L to the upper surface of the third semiconductor layer 105L is in the range of about 150 nm to about 700 nm, for example, about 200 nm to about 500 nm, or from about 150 nm to about 325 nm. In this region, in an example, the thickness of layer 104L may be greater than the thicknesses of 103L or 105L. By using epitaxially grown layers for the first to third semiconductor regions 103, 104, and 105, the doping profile may be easily controlled while significantly reducing the first thickness T1 compared to the case of using an ion implantation process.

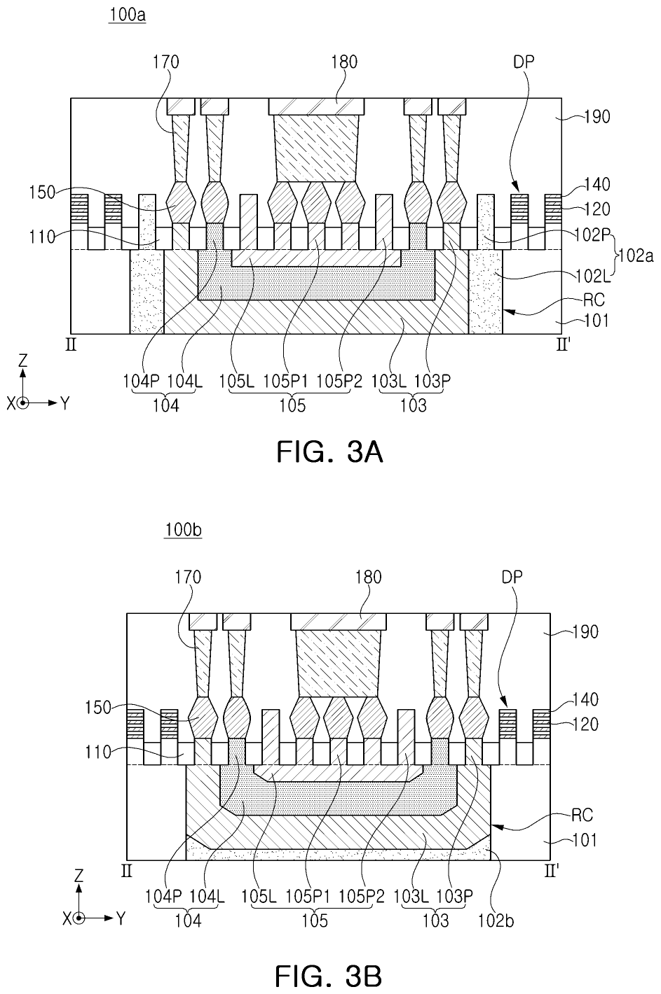

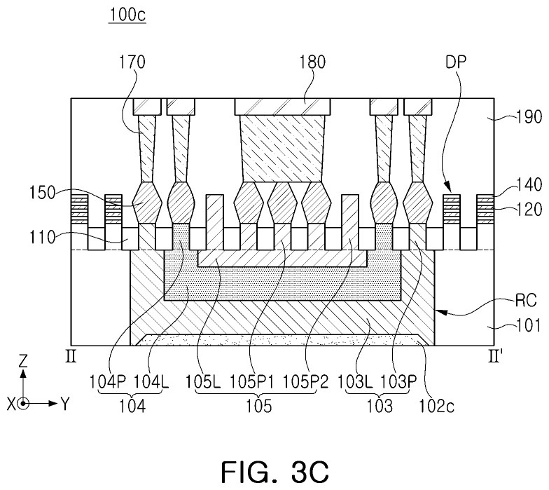

The epitaxial stopper layer 102 may be disposed between the substrate 101 and the first semiconductor region 103 and may be disposed to contact the bottom surface and inner side surfaces of structure disposed within the recessed region RC. The epitaxial stopper layer 102 may include a stopper layer 102L disposed in the recessed region RC and stopper protrusions 102P disposed on an upper surface of the stopper layer 102L. The epitaxial stopper layer 102 may be used as an etch stop layer or a planarization stop layer during a backside thinning process in which a portion of the substrate 101 is removed from the lower surface. The epitaxial stopper layer 102 may cover at least a portion of an outer surface of the first semiconductor region 103. The first semiconductor region 103 may vertically overlap epitaxial stopper layer 102, and epitaxial stopper layer 102 may extend upward along outer side surfaces of the first semiconductor region 103 and inner side surfaces of the recessed region RC. In the example of FIGS. 2A and 2B, the entire area of first semiconductor region 103 is disposed above at least part of epitaxial stopper layer 102 (though in other examples such as that of FIG. 3C, the entire area of semiconductor region 103 is not disposed above stopper layer 102).

In a plan view, the epitaxial stopper layer 102 may be disposed to surround the first semiconductor region 103. In the Z-direction, the entirety of the first to third semiconductor regions 103, 104, and 105 may overlap the epitaxial stopper layer 102. The stopper protrusions 102P may be located at substantially the same level as the third outer protrusions 105P2, but are not limited thereto.

The epitaxial stopper layer 102 may be an epitaxial layer including a semiconductor material. The epitaxial stopper layer 102 may include a material having a selectivity with the substrate 101 and may include a material or element different from that of the substrate 101. The epitaxial stopper layer may be a crystalline silicon region deposited within the recessed region RC, for example having a single domain epitaxy.

In addition, the epitaxial stopper layer 102 may include a material or element different from those of the first to third semiconductor regions 103, 104, and 105. For example, the substrate 101 may include Si or Si:B, for example, silicon (Si) doped with boron (B), the first and third semiconductor regions 103 and 105 may include Si:B, the second semiconductor region 104 may include Si:P, and the epitaxial stopper layer 102 may include at least one of SiGe, Si:C, Si:As, and SiGe:C. The epitaxial stopper layer 102 may not have a conductivity type, but is not limited thereto.

The epitaxial stopper layer 102 has a second thickness T2 on inner side surfaces of the recessed region RC, and on the bottom surface of the recessed region RC, a third thickness T3 smaller than the second thickness T2 may be provided. The third thickness T3 may be, for example, in a range of about 10 nm to about 100 nm.

The epitaxial stopper layer 102 may prevent damage to the first to third semiconductor regions 103, 104, and 105 during the aforementioned thinning process. In addition, by applying the epitaxial stopper layer 102, the thickness variation of the substrate 101 remaining after the thinning process may be significantly reduced.

The dummy protrusions DP may be disposed outside of the first to third protrusions 103P, 104P, and 105P to include regions extending upward from the substrate 101, and may have a shape extending in the X-direction. The dummy protrusions DP may include channel layers 140 and sacrificial layers 120 alternately disposed on the substrate 101. The sacrificial layers 120 may include a semiconductor material different from that of the channel layers 140. For example, the channel layers 140 may include silicon (Si), and the sacrificial layers 120 may include silicon germanium (SiGe). Upper surfaces of the dummy protrusions DP may be positioned at the same level as, for example, upper surfaces of the third outer protrusions 105P2, but are not limited thereto.

The device isolation layer 110 may be disposed to define at least in part, and to electrically separate, the first to third protrusions 103P, 104P, and 105P, the stopper protrusions 102P, and the dummy protrusions DP. The device isolation layer 110 may be formed by, for example, a shallow trench isolation (STI) process. The device isolation layer 110 may be formed of an insulating material. The device isolation layer 110 may include, for example, oxide, nitride, or a combination thereof.

The dummy gate structures DGS may extend in the Y-direction crossing the first to third protrusions 103P, 104P, and 105P, the stopper protrusions 102P, and the dummy protrusions DP, and may be arranged to be spaced apart from each other in the X-direction. The dummy gate structures DGS may be spaced apart from each other between the first and second protrusions 103P and 104P and may be spaced apart from each other between the second and third protrusions 104P and 105P in the Y-direction. The dummy gate structures DGS may be spaced apart from each other between the first protrusions 103P and the stopper protrusions 102P and may be spaced apart from each other between the stopper protrusions 102P and the dummy protrusions DP. However, positions of regions in which the dummy gate structures DGS are spaced apart from each other in the Y-direction may be changed in embodiments.

The dummy gate structures DGS may be components to which electrical signals are not applied and/or layers that do not substantially perform electrical functions in the semiconductor device 100. As illustrated in FIG. 2A, the dummy gate structure DGS may include a gate dielectric layer 162, gate spacer layers 164, a gate electrode 165, and a gate capping layer 166.

Though not illustrated, the gate dielectric layer 162 may also be disposed between the gate electrode 165 and a protrusion such as the first to third protrusions 103P, 104P, and 105P, and the gate dielectric layer 162 may be disposed to cover at least a portion of surfaces of the gate electrode 165. For example, the gate dielectric layer 162 may be disposed to surround all surfaces except for the upper surface of the gate electrode 165. The gate dielectric layer 162 may also extend between the gate electrode 165 and the gate spacer layers 164, but is not limited thereto. The gate dielectric layer 162 may include an oxide, nitride, or high-k material. The high-κ material may mean a dielectric material having a higher dielectric constant than silicon oxide (SiO₂). According to embodiments, the gate dielectric layer 162 may be formed of a multi-layered film.

The gate electrode 165 may include a conductive material, and for example, may include a metal nitride such as titanium nitride (TiN), tantalum nitride (TaN), or tungsten nitride (WN), and/or a metal material such as aluminum (Al), tungsten (W), or molybdenum (Mo), or a semiconductor material such as doped polysilicon. According to embodiments, the gate electrode 165 may be composed of two or more multi-layers.

A gate capping layer 166 may be disposed on the gate electrode 165. The gate capping layer 166 may include an insulating material. In some embodiments, the relative disposition of the gate capping layer 166, the gate spacer layers 164, and the interlayer insulating layer 190 and the position of the interface may be changed.

The gate spacer layers 164 may be disposed on both side surfaces of the gate electrode 165 and the gate capping layer 166 in the X-direction. According to embodiments, the shapes of the gate spacer layers 164 may be changed, and the gate spacer layers 164 may have a multilayer structure. The gate spacer layers 164 may include at least one of oxide, nitride, and oxynitride, and may include, for example, a low-κ material.

The source layers 150 may be disposed on at least portions of the first to third protrusions 103P, 104P, and 105P and disposed on one or both sides of the dummy gate structures DGS in the X-direction. The source layers 150 may be disposed in upper recessed regions of the first to third protrusions 103P, 104P, and 105P. The source layers 150 may be connected to the upper contact plugs 170.

As illustrated in FIG. 2B, the source layers 150 may have polygonal or elliptical shapes outside of the dummy gate structures DGS, but are not limited thereto. The source layers 150 on the first and third protrusions 103P and 105P have a first conductivity type including the first conductivity type impurities, and the source layers 150 on the second protrusions 104P may have a second conductivity type by including the second conductivity type impurities. The source layers 150 may have different shapes on the first and third protrusions 103P and 105P and on the second protrusions 104P, depending on the type of material. For example, the source layers 150 may have a relatively polygonal shape on the first and third protrusions 103P and 105P, and may have a shape close to an ellipse on the second protrusions 104P, but are not limited thereto.

The contact plugs 170 may pass through the interlayer insulating layer 190 and be connected to the source layers 150. Electrical signals may be applied to the first to third semiconductor regions 103, 104, and 105 through the source layers 150. The contact plugs 170 may have inclined side surfaces where the width of the lower part is narrower than the width of the upper part according to the aspect ratio, but is not limited thereto. The depth of the contact plugs 170 may be changed in the example embodiments.

In some embodiments, the contact plugs 170 may include a metal silicide layer positioned in a region in contact with the source layers 150, and a barrier layer disposed on an upper surface of the metal silicide layer and sidewalls of the contact plugs 170 may be further included. The barrier layer may include, for example, a metal nitride such as titanium nitride (TiN), tantalum nitride (TaN), or tungsten nitride (WN). The contact plugs 170 may include, for example, a metal material such as aluminum (Al), tungsten (W), or molybdenum (Mo). In example embodiments, the number and arrangement of conductive layers constituting the contact plugs 170 may be changed.

The interconnection lines 180 may be connected to the contact plugs 170 on the contact plugs 170. The interconnection lines 180 electrically connected to the first to third semiconductor regions 103, 104, and 105 may be spaced apart from each other and electrically separated from each other. The interconnection lines 180 may include, for example, a metal material such as aluminum (Al), tungsten (W), or molybdenum (Mo).

The interlayer insulating layer 190 may be disposed to cover upper surfaces of the device isolation layer 110 and the source layers 150. The interlayer insulating layer 190 may include at least one of an oxide, a nitride, and an oxynitride, and may include, for example, a low dielectric constant material. According to embodiments, each interlayer insulating layer 190 may include a plurality of insulating layers.

In the description of the following embodiments, descriptions overlapping with those described above with reference to FIGS. 1 to 2B will be omitted.

FIGS. 3A to 3C are schematic cross-sectional views illustrating a semiconductor device according to example embodiments. FIGS. 3A to 3C each illustrate a region corresponding to FIG. 2B.

Referring to FIG. 3A, in the semiconductor device 100a, the epitaxial stopper layer 102a may not be disposed on the lower surface of the first semiconductor layer 103L, and may be disposed only on outer side surfaces of the first semiconductor layer 103L. The epitaxial stopper layer 102a may be entirely removed from the lower surface of the first semiconductor layer 103L during the manufacturing process of the semiconductor device 100a.

Referring to FIG. 3B, in the semiconductor device 100b, the epitaxial stopper layer 102b may be disposed only on the lower surface of the first semiconductor layer 104L. For example, the epitaxial stopper layer 102b may be disposed only on the bottom surface of the recessed region RC and may not extend upward along inner side surfaces. Accordingly, the outer side surfaces of the first semiconductor layer 103L may contact the substrate 101.

In addition, the epitaxial stopper layer 102b may include a facet region whose thickness increases in an edge region approaching substrate 101. The facet region may include an inclined surface that is a facet along a crystal plane. The facet region may be formed by controlling growth conditions during the growth process of the epitaxial stopper layer 102b so that growth occurs from the bottom surface of the recessed region RC along the crystal plane. Accordingly, the first semiconductor layer 103L may also have a facet corresponding to the facet at a corner region in contact with the epitaxial stopper layer 102b. Each of the second and third semiconductor layers 104L and 105L may also have a facet at a corner region.

Referring to FIG. 3C, in the semiconductor device 100c, the epitaxial stopper layer 102c may be disposed only on the lower surface of the first semiconductor layer 104L as in the example embodiment of FIG. 3B, and may include a facet region. However, the facet region of the epitaxial stopper layer 102c may have a shape in which the thickness decreases in an edge region approaching substrate 101.

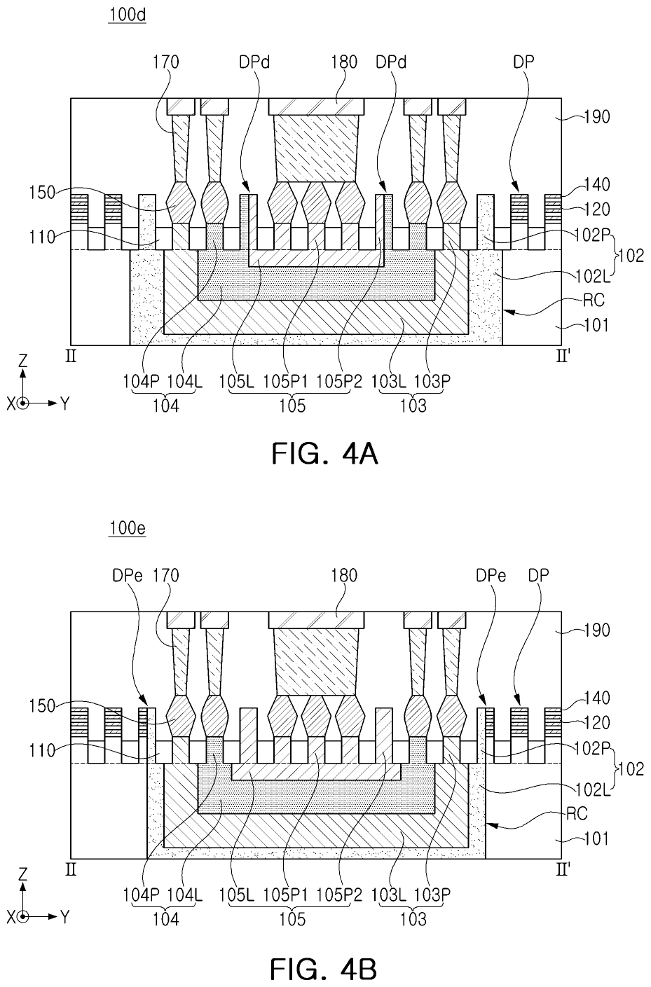

FIGS. 4A and 4B are schematic cross-sectional views illustrating a semiconductor device according to example embodiments. FIGS. 4A and 4B each illustrate a region corresponding to FIG. 2B.

Referring to FIG. 4A, in the semiconductor device 100d, the dummy protrusions DP may be referred to as first dummy protrusions DP. The semiconductor device 100d may further include second dummy protrusions DPd.

Each of the second dummy protrusions DPd may be disposed between the second protrusion 104P and the third protrusion 105P. In the second dummy protrusion DPd, and the outer region facing the second protrusion 104P includes the same material as the second protrusion 104P and has a second conductivity type, and an inner region facing the third protrusion 105P may include the same material as the third protrusion 105P and have the first conductivity type. In some embodiments, the dummy protrusion of this type may be disposed between the first protrusion 103P and the second protrusion 104P, or may be further disposed.

Referring to FIG. 4B, in the semiconductor device 100e, the dummy protrusions DP may be referred to as first dummy protrusions DP. The semiconductor device 100e may further include second dummy protrusions DPe.

The second dummy protrusions DPe may be respectively disposed between the first protrusion 103P and the first dummy protrusion DP. In the second dummy protrusion DPe, an outer area facing the first dummy protrusion DP has the same structure as the first dummy protrusion DP, and an inner region facing the first protrusion 103P and forming the stopper protrusion 102P may include the same material as the stopper protrusion 102P. In some embodiments, the second dummy protrusion DPe of this type may be further disposed between the stopper protrusion 102P as illustrated in FIG. 2B and the first dummy protrusion DP, or may be additionally arranged in the example embodiment of FIG. 4A.

As in the example embodiments of FIGS. 4A and 4B, various types of dummy protrusions may be disposed between adjacent protrusions among the first to third protrusions 103P, 104P, and 105P, the stopper protrusions 102P, and the dummy protrusions DP in a similar manner.

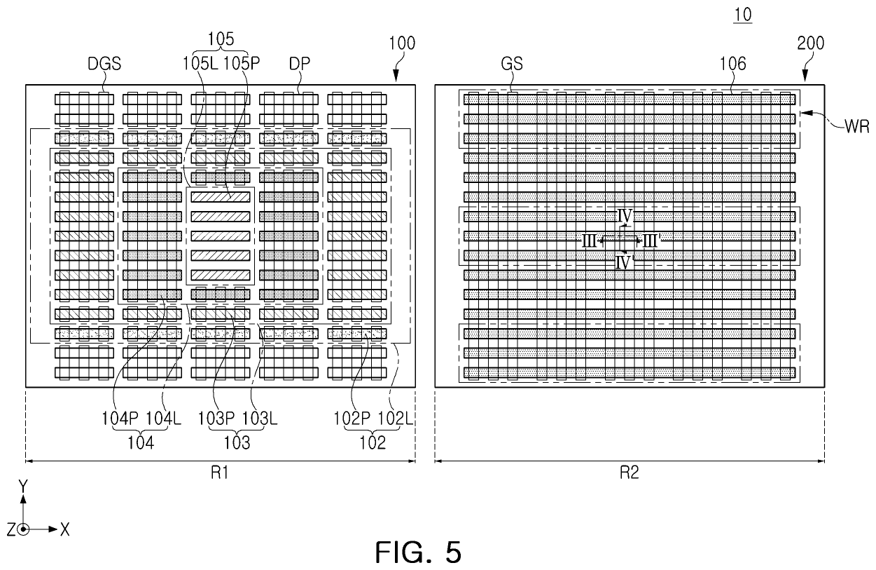

FIG. 5 is a plan view illustrating a semiconductor device according to example embodiments.

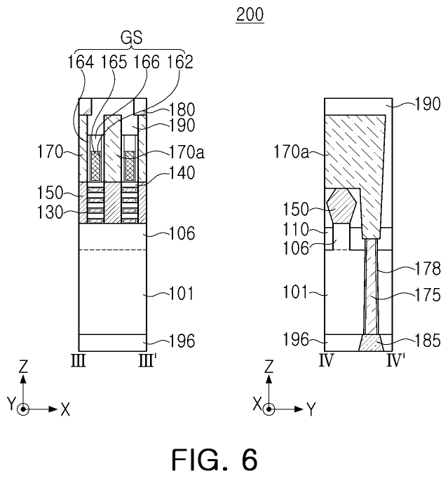

FIG. 6 are cross-sectional views illustrating a semiconductor device according to example embodiments. FIG. 6 illustrates cross-sections of the semiconductor device of FIG. 5 taken along cutting lines III-III and IV-IV. For convenience of description, only some components of the semiconductor device are illustrated in FIG. 5.

Referring to FIGS. 5 and 6, the semiconductor device 10 may include a first device region R1 including the first device 100 and a second device region R2 including the second device 200. The first device region R1 and the second device region R2 may be adjacent to or separated from each other. The description of the semiconductor device 100 described above with reference to FIGS. 1 to 2B may be equally applied to the first device 100.

The second element 200 may include a substrate 101 including well regions WR, an active region 106 on substrate 101, channel layers 140 disposed vertically spaced apart from each other on the active region 106, a gate structure GS extending to cross the active region 106, source layers 150 in contact with the channel layers 140, first and second contact plugs 170 and 170a connected to the source layers 150, and interconnection lines 180 on the first contact plugs 170. The second element 200 may further include inner spacer layers 130, buried interconnection line 185 below the active region 106, a backside contact plug 175, a contact insulating layer 178, a device isolation layer 110, and first and second interlayers insulating layers 190 and 196. The same reference numerals as in the above description with reference to FIGS. 1 to 2B mean the same configuration, and duplicate descriptions will be omitted below.

In the second element 200, the active region 106 may have a fin shape, and the gate electrode 165 may be disposed between the active region 106 and the channel layers 140, between respective layers of the channel layers 140, and above the channel layers 140. Accordingly, the second element 200 may include a multi bridge channel FET (MBCFET™) structure transistor, which is a gate-all-around type field effect transistor.

The active region 106 and the channel layers 140 may form protrusions. The active region 106 may extend in a line shape in the X-direction on the substrate 101. In the first device region R1 and the second device region R2, the lower surface of the substrate 101 may be coplanar, but is not limited thereto.

Channel layers 140 may be disposed on the active region 106 in regions where the active region 106 intersects the gate structure GS. The channel layers 140 may include two or more layers spaced apart from each other in the Z-direction. The channel layers 140 may be connected to the source layers 150. The channel layers 140 may have a width equal to or smaller than that of the active region 106 in the Y-direction, and may have the same width as or smaller than that of the gate structure GS in the X-direction. The channel layers 140 may be formed of a semiconductor material, and may include, for example, at least one of silicon (Si), silicon germanium (SiGe), and germanium (Ge).

The inner spacer layers 130 may be disposed parallel to the gate structure GS between the channel layers 140 in the Z-direction. The inner spacer layers 130 may include at least one of oxide, nitride, and oxynitride, and may include, for example, a low dielectric constant material. However, according to embodiments, the internal spacer layers 130 may be omitted.

The gate structure GS may be disposed to cross the active region 106 and the channel layers 140 and extend in the second direction, for example, the Y-direction. Channel regions of transistors may be formed in the channel layers 140 crossing the gate electrode 165 of the gate structure GS. The gate structure GS includes a gate electrode 165, gate dielectric layers 162 between the gate electrode 165 and the channel layers 140, gate spacer layers 164 on side surfaces of the gate electrode 165, and a gate capping layer 166. The gate structure GS may be formed together with the dummy gate structure DGS of the first device 100 to have the same structure.

The source layers 150 may function as source/drain regions in the second element 200. Portions of the source layers 150 are electrically connected to the upper interconnection lines 180 through the first contact plugs 170, and the other part may be electrically connected to the buried interconnection line 185 below the substrate 101 through the second contact plug 170a. The second contact plug 170a is connected to at least a portion of the source layers 150, and at least one side thereof may extend into the device isolation layer 110 as illustrated in FIG. 6. However, according to embodiments, the depth at which the second contact plug 170a extends may be changed. For example, in some embodiments, the second contact plug 170a may extend to the lower surface of the substrate 101, and in this case, the backside contact plug 175 may be omitted. The second contact plug 170a may have a shape in which the width is narrowed while facing downward, and may be connected to the backside contact plug 175 on the lower end. The second contact plug 170a may include a metal material such as aluminum (Al), tungsten (W), or molybdenum (Mo).

The buried interconnection line 185 may be disposed below the substrate 101 and the active region 106. The buried interconnection line 185 may be positioned at a level lower than the epitaxial stopper layer 102 of the first element 100. The buried interconnection line 185 may be arranged to extend in one direction, for example, the X-direction, but is not limited thereto. The buried interconnection line 185 may be a power interconnection line for applying power or a ground voltage, and may also be referred to as a buried power rail. The buried interconnection line 185 may be electrically connected to at least a portion of the source layers 150. The buried interconnection line 185 may be formed of a metal material, for example, at least one of tungsten (W), copper (Cu), aluminum (Al), cobalt (Co), ruthenium (Ru), titanium (Ti), and molybdenum (Mo).

The backside contact plug 175 may connect the second contact plug 170a and the buried interconnection line 185. The backside contact plug 175 may pass through the substrate 101 and the device isolation layer 110 and be connected to the second contact plug 170a. The backside contact plug 175 may have a cylindrical shape or a truncated cone shape, and may have a shape in which the width is narrowed toward the top. The backside contact plug 175 may be spaced apart from the substrate 101 by the contact insulating layer 178. In some embodiments, the substrate 101 may be completely removed from the second device region R2. In this case, the backside contact plug 175 may extend only into the device isolation layer 110 and the contact insulating layer 178 may also be omitted.

The backside contact plug 175 may include a metal material, for example, at least one of tungsten (W), copper (Cu), aluminum (Al), cobalt (Co), ruthenium (Ru), titanium (Ti), and molybdenum (Mo). The contact insulating layer 178 may include an insulating material.

The second interlayer insulating layer 196 may be disposed to surround the buried interconnection line 185. The second interlayer insulating layer 196 may include at least one of oxide, nitride, and oxynitride, and may include, for example, a low dielectric constant material. In the semiconductor device 10, a second interlayer insulating layer 196 may be further disposed on the lower surfaces of the substrate 101 and the epitaxial stopper layer 102 of the first device region R1.

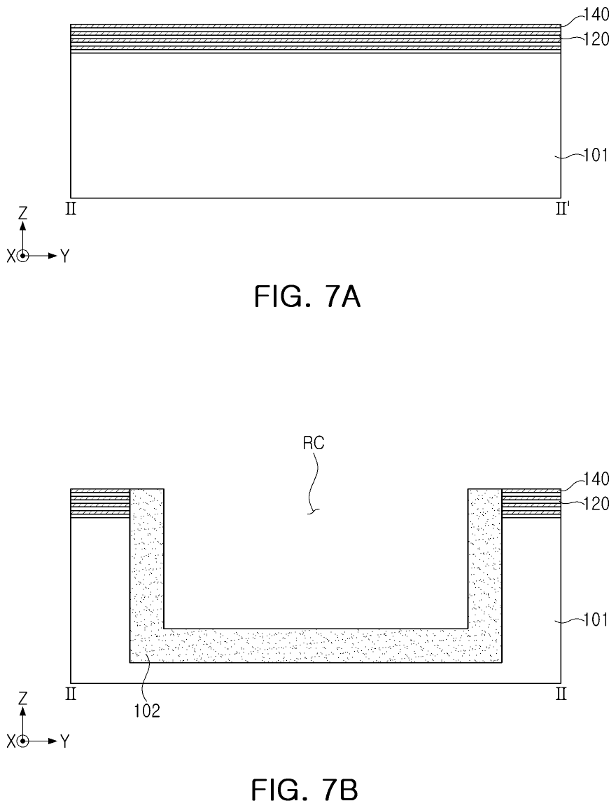

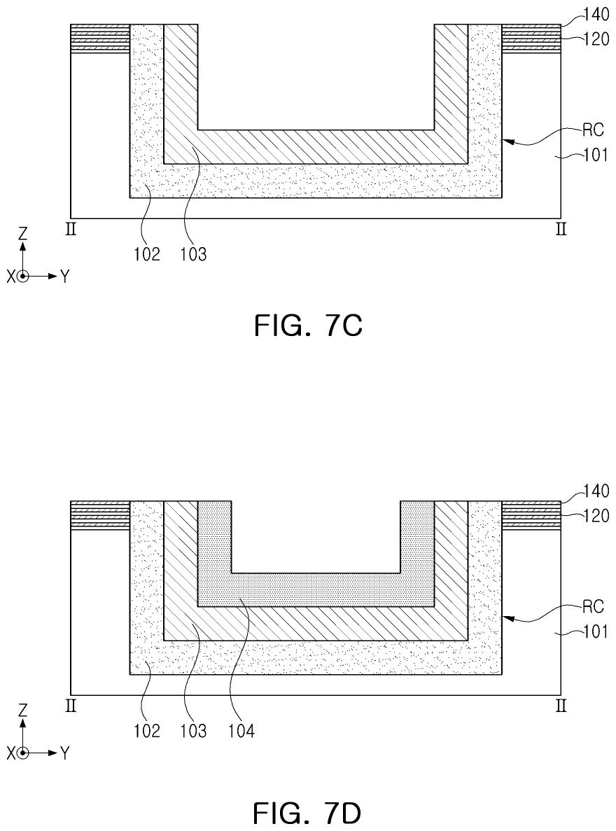

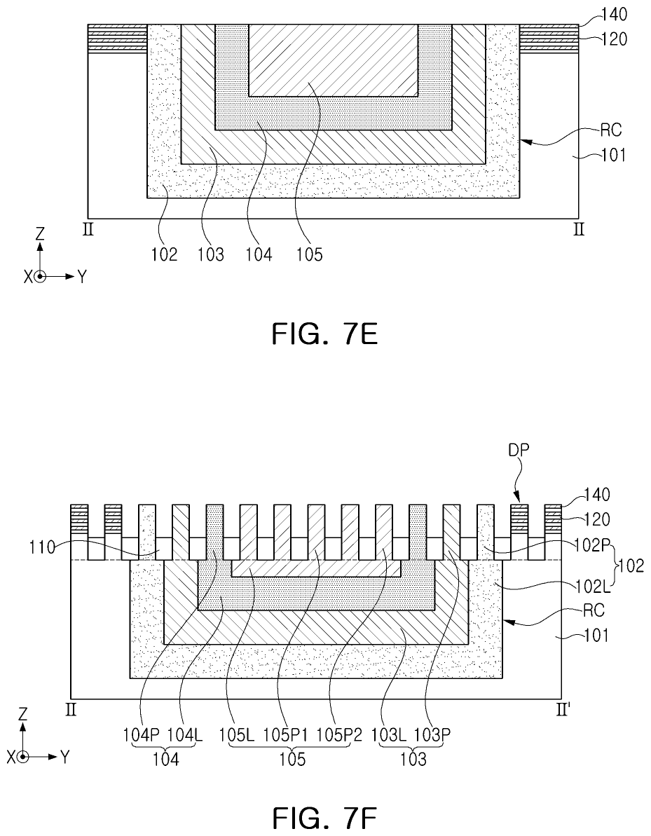

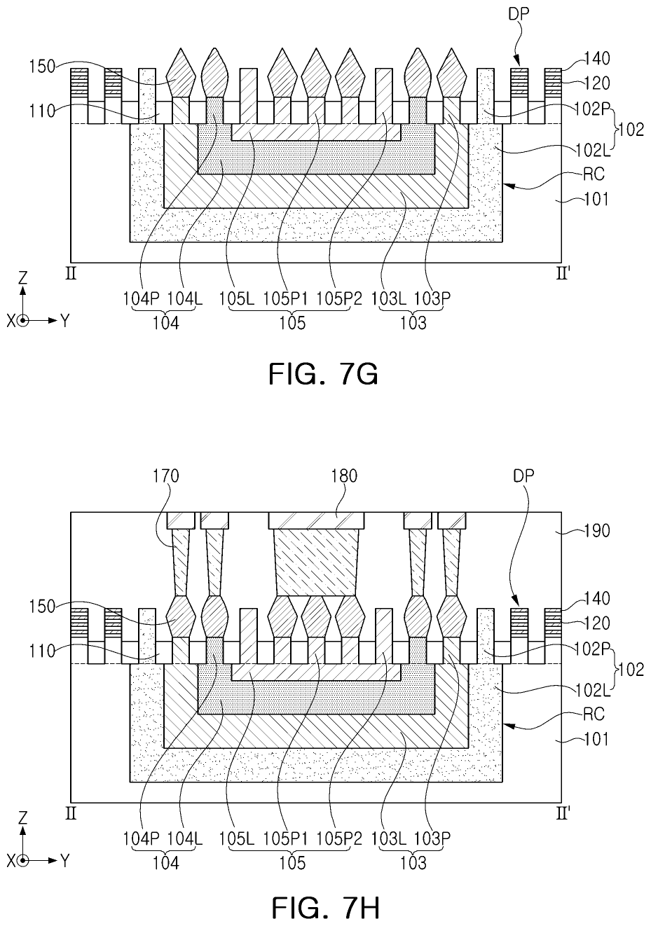

FIGS. 7A to 7H are views illustrating a process sequence to describe a method of manufacturing a semiconductor device according to example embodiments. FIGS. 7A to 7H illustrate an example embodiment of a method of manufacturing the semiconductor device of FIGS. 1 to 2B, and illustrate a cross section corresponding to FIG. 2B.

Referring to FIG. 7A, sacrificial layers 120 and channel layers 140 may be alternately stacked on a substrate 101.

The substrate 101 may be, for example, a substrate including a semiconductor wafer. The sacrificial layers 120 may be layers that are replaced with the gate dielectric layer 162 and the gate electrode 165 in some regions, for example, the second device region R2 of the example embodiment of FIGS. 5 and 6 through a subsequent process. The sacrificial layers 120 and the channel layers 140 may be formed by performing an epitaxial growth process on the substrate 101. The number of layers of the channel layers 140 alternately stacked with the sacrificial layers 120 may be changed in embodiments.

The sacrificial layers 120 may be formed of a material having etch selectivity with respect to the channel layers 140. The sacrificial layers 120 and the channel layers 140 include, for example, a semiconductor material including at least one of silicon (Si), silicon germanium (SiGe), and germanium (Ge), but may include different substances, and may or may not contain impurities. For example, the sacrificial layers 120 may include silicon germanium (SiGe), and the channel layers 140 may include silicon (Si).

Referring to FIG. 7B, a recessed region RC may be formed by partially removing the stacked structure of the sacrificial layers 120, and channel layers 140, as well as at least part of substrate 101 in the region where the stacked structure is removed. Then, the epitaxial stopper layer 102 may be formed within the recessed region RC.

The stacked structure and substrate may be removed by an etching process. An epitaxial stopper layer 102 may be formed by performing an epitaxial growth process on a region from which the stacked structure is removed. The epitaxial stopper layer 102 may be formed on the bottom surface and inner side surfaces of the recessed region RC. The epitaxial stopper layer 102 may include a material different from that of the substrate 101, for example, a different element. Referring to FIG. 7C, a first semiconductor region 103 may be formed on the epitaxial stopper layer 102.

The first semiconductor region 103 may be grown from the epitaxial stopper layer 102 by performing an epitaxial growth process. For example, the first semiconductor region 103 may be formed in a continuous process in the same chamber as the chamber in which the epitaxial stopper layer 102 is formed. The first semiconductor region 103 may include, for example, silicon (Si) and may include first conductivity-type impurities doped in situ. The first semiconductor region 103 may include a material different from that of the epitaxial stopper layer 102.

In embodiments, according to the growth characteristics in the crystal plane, a thickness of the horizontal region grown from the upper surface of the epitaxial stopper layer 102 and a thickness of the vertical region grown from the inner side surface of the epitaxial stopper layer 102 may be the same or different.

Referring to FIG. 7D, a second semiconductor region 104 may be formed on the first semiconductor region 103.

The second semiconductor region 104 may be grown from the first semiconductor region 103 by performing an epitaxial growth process. For example, the second semiconductor region 104 may be continuously formed in the same chamber as the chamber in which the first semiconductor region 103 is formed. The second semiconductor region 104 may include, for example, silicon (Si) and may include second conductivity-type impurities doped in situ.

Referring to FIG. 7E, a third semiconductor region 105 may be formed on the second semiconductor region 104.

The third semiconductor region 105 may be grown from the second semiconductor region 104 by performing an epitaxial growth process. For example, the third semiconductor region 105 may be formed in a continuous process in the same chamber as the chamber in which the second semiconductor region 104 is formed. The third semiconductor region 105 may be formed to fill the recessed region RC. The third semiconductor region 105 may include, for example, silicon (Si) and may include first conductivity type impurities doped in situ.

Referring to FIG. 7F, the substrate 101, the sacrificial layers 120, the channel layers 140, the epitaxial stopper layer 102, and the first to third semiconductor regions 103, 104, and 105 may be partially removed, to form first to third protrusions 103P, 104P, and 105P, stopper protrusions 102P, and dummy protrusions DP, and a device isolation layer 110 may be formed.

The first to third protrusions 103P, 104P, and 105P, the stopper protrusions 102P, and the dummy protrusions DP may be respectively formed in a line shape extending in one direction, for example, the X-direction, and may be formed spaced apart from each other in the Y-direction. In this operation, the first to third protrusions 103P, 104P, and 105P, the stopper protrusions 102P, and the dummy protrusions DP may have substantially the same height and width. Accordingly, the first to third semiconductor regions 103, 104, and 105 include the first to third semiconductor layers 103L, 104L, and 105L and the first to third protrusions 103P, 104P, and 105P, respectively, and the epitaxial stopper layer 102 may be formed to include a stopper layer 102L and a stopper protrusion 102P.

The device isolation layer 110 may be formed by filling the insulating material in a region in which portions of the substrate 101, the sacrificial layers 120, the channel layers 140, the epitaxial stopper layer 102, and the first to third semiconductor regions 103, 104, and 105 have been respectively removed and then by removing a portion of the insulating material. An upper surface of the device isolation layer 110 may be lower than upper surfaces of the first to third protrusions 103P, 104P, and 105P.

Referring to FIG. 7G, upper regions of portions of the first to third protrusions 103P, 104P, and 105P are removed to form recessed regions, and source layers 150 may be formed in the recessed regions.

First, sacrificial gate structures and gate spacer layers 164 may be formed in regions corresponding to the dummy gate structures DGS (see FIGS. 1 and 2A). The sacrificial gate structures may be structures formed in a region where the gate dielectric layer 162, the gate electrode 165, and the gate capping layer 166 are disposed at a level higher than the channel layers 140, in a subsequent process. Gate spacer layers 164 may be formed on both sidewalls of the sacrificial gate structure. The gate spacer layers 164 may be formed of a low-κ material, and may include, for example, at least one of SiO, SiN, SiCN, SiOC, SiON, and SiOCN.

Next, using the sacrificial gate structures, the gate spacer layers 164, and an additional mask layer as masks, the recessed regions may be formed by removing at least a portion of the exposed first to third protrusions 103P, 104P, and 105P. In some embodiments, all of the first to third protrusions 103P, 104P, and 105P may be recessed according to the range of the additional mask layer, or the stopper protrusions 102P and/or the dummy protrusions DP may be further recessed.

The source layers 150 may be formed by growing the recessed regions through an epitaxial process. The source layers 150 may include impurities by in-situ doping, and may include a plurality of layers having different doping elements and/or doping concentrations. The source layers 150 may include first conductivity type impurities on the first and third protrusions 103P and 105P, and may include second conductivity type impurities on the second protrusion 104P.

Referring to FIG. 7H, contact plugs 170 and interconnection lines 180 may be formed.

First, the interlayer insulating layer 190 may be formed by forming an insulating film covering the source layers 150 and performing a planarization process. Next, the sacrificial gate structures may be removed, and dummy gate structures DGS (see FIGS. 1 and 2A) may be formed.

In the case of the example embodiment of FIGS. 5 and 6, after removing the sacrificial gate structures in the second device region R2, the sacrificial layers 120 may be further removed, and gate structures GS may be formed.

Next, an interlayer insulating layer 190 may be further formed on the dummy gate structures DGS, and contact holes exposing the source layers 150 may be formed by partially removing the interlayer insulating layer 190. Contact plugs 170 may be formed by filling the contact holes with a conductive material. Interconnection lines 180 may be formed on the contact plugs 170.

Next, referring to FIG. 2B together, a process of thinning the substrate 101 by partially removing it from the lower surface may be performed.

The thinning process may include an etching process and/or a chemical mechanical polishing (CMP) process. During the thinning process, the epitaxial stopper layer 102 may function as a thinning stop layer. Accordingly, the epitaxial stopper layer 102 may be exposed downward. In this step, the epitaxial stopper layer 102 may also be partially removed to reduce the thickness of the stopper layer 102L, but is not limited thereto.

In the case of the example embodiment of FIGS. 5 and 6, a backside contact plug 175 may be formed from the lower surface of the substrate 101 in the second element region R2, and may be manufactured by forming a buried interconnection line 185 on the lower surface of the substrate 101.

As set forth above, a semiconductor device having improved integration and electrical characteristics may be provided by including a vertical PNP device that includes epitaxially grown semiconductor regions and an epitaxial stopper layer.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a substrate having a recessed region;
a first semiconductor region including a first semiconductor layer on a bottom surface and an inner side surface of the recessed region and a first protrusion on an upper surface of the first semiconductor layer, and having a first conductivity type;
a second semiconductor region including a second semiconductor layer on the first semiconductor layer in the recessed region and a second protrusion on an upper surface of the second semiconductor layer, and having a second conductivity type;
a third semiconductor region including a third semiconductor layer on the second semiconductor layer in the recessed region and a third protrusion on an upper surface of the third semiconductor layer, and having the first conductivity type;
an epitaxial stopper layer covering the bottom surface of the recessed region between the first semiconductor region and the substrate, and including a material different from materials of the first to third semiconductor regions; and
a dummy gate structure on at least one of the first to third protrusions on the substrate.

2. The semiconductor device of claim 1, wherein an entirety of the third semiconductor region overlaps the first and second semiconductor regions and the epitaxial stopper layer in a direction perpendicular to an upper surface of the substrate.

3. The semiconductor device of claim 1, wherein in a plan view, the first semiconductor region surrounds the second semiconductor region and the second semiconductor region surrounds the third semiconductor region.

4. The semiconductor device of claim 3, wherein in the plan view, the epitaxial stopper layer surrounds the first semiconductor region.

5. The semiconductor device of claim 1, wherein the epitaxial stopper layer includes at least one of SiGe, Si:C, Si:As, and SiGe:C.

6. The semiconductor device of claim 1, wherein each of the first to third semiconductor regions is formed of an epitaxial layer.

7. The semiconductor device of claim 1, wherein the epitaxial stopper layer contacts the inner side surface of the recessed region, extends upwardly along the inner side surface, has a first thickness on the inner side surface of the recessed region, and has a second thickness less than the first thickness on the bottom surface of the recessed region.

8. The semiconductor device of claim 1, wherein the epitaxial stopper layer includes a stopper layer in the recessed region and a stopper protrusion on an upper surface of the stopper layer.

9. The semiconductor device of claim 1, wherein the epitaxial stopper layer is on the bottom surface of the recessed region, without extending along the inner side surface of the recessed region.

10. The semiconductor device of claim 9, wherein the epitaxial stopper layer has a facet along a crystal plane in an edge region.

11. The semiconductor device of claim 1, further comprising a dummy protrusion between the second protrusion and the third protrusion and including a first region having the second conductivity type and a second region having the first conductivity type.

12. The semiconductor device of claim 1, wherein a thickness from a lower surface of the first semiconductor layer to the upper surface of the third semiconductor layer ranges from about 150 nm to about 700 nm.

13. The semiconductor device of claim 1, further comprising:
a first source layer on the first protrusion, outside of the dummy gate structure, and having the first conductivity type;
a second source layer on the second protrusion, outside of the dummy gate structure, and having the second conductivity type; and
a third source layer on the third protrusion, outside of the dummy gate structure, and having the first conductivity type.

14. The semiconductor device of claim 13, further comprising contact plugs on the first to third source layers.

15. A semiconductor device comprising:
a substrate having a first region on which a recessed region is disposed and a second region;
a first semiconductor region on a bottom surface and an inner side surface of the recessed region and including first conductivity type impurities;
a second semiconductor region on the first semiconductor region in the recessed region and including second conductivity type impurities;
a third semiconductor region on the second semiconductor region in the recessed region and including the first conductivity type impurities; and
an epitaxial stopper layer covering at least a portion of outer surfaces of the first semiconductor region including a bottom surface,
wherein each of the first to third semiconductor regions is formed of an epitaxial layer.

16. The semiconductor device of claim 15, wherein the epitaxial stopper layer includes a material different from materials of the first to third semiconductor regions.

17. The semiconductor device of claim 15, further comprising interconnection lines on the first to third semiconductor regions and a buried interconnection line on a level lower than a level of the epitaxial stopper layer.

18. The semiconductor device of claim 15, further comprising a logic element in the second region,
wherein the logic element includes,
an active region;
a gate structure extending on the active region and crossing the active region;
a plurality of channel layers on the active region, spaced apart from each other in a direction, perpendicular to an upper surface of the active region, and surrounded by the gate structure;
source layers on both sides of the gate structure; and
a buried interconnection line below the source layers and electrically connected to at least a portion of the source layers.

19. A semiconductor device comprising:
a substrate having a recessed region;
a first semiconductor region on a bottom surface and an inner side surface of the recessed region and including first conductivity type impurities;
a second semiconductor region on the first semiconductor region in the recessed region and including second conductivity type impurities;
a third semiconductor region on the second semiconductor region in the recessed region and including the first conductivity type impurities; and
an epitaxial stopper layer covering at least a portion of outer surfaces of the first semiconductor region including a bottom surface,
wherein the first to third semiconductor regions and the epitaxial stopper layer have a region entirely overlapping in a direction, perpendicular to an upper surface of the substrate.

20. The semiconductor device of claim 19, wherein the epitaxial stopper layer has a first thickness on the inner side surface of the recessed region, and has a second thickness less than the first thickness, on the bottom surface of the recessed region.
